(19) United States
(12) Patent Application Publication
(10) Pub. No.: US 2015/0067619 A1
(43) Pub. Date: Mar. 5, 2015

(54) ADVANCED CORRECTION METHOD

(71) Applicant: MACRONIX International Co., Ltd., Hsinchu (TW)

(72) Inventors: Chung-Te Hsuan, Hsinchu (TW); Che-Ming Hu, Hsinchu (TW); Chao-Lung Lo, Hsinchu (TW)

(73) Assignee: MACRONIX International Co., Ltd., Hsinchu (TW)

(21) Appl. No.: 14/272,077

(22) Filed: May 7, 2014

Related U.S. Application Data
(60) Provisional application No. 61/870,788, filed on Aug. 28, 2013.

(51) Int. Cl. G03F 7/20

(52) U.S. Cl. CPC G03F 7/70441
USPC 716/53

(57) ABSTRACT

An advanced correction method is provided. A target layout pattern is provided, and is corrected by a correction model to obtain a corrected pattern. A simulation is performed on the corrected pattern to obtain a simulation contour. A plurality of off-target evaluation points are established on the simulation contour, the simulation contour is compared with a target layout pattern, and a plurality of risk weighting values of each of the off-target evaluation points are obtained. A risk sum value obtained by summing up the risk weighting values of each of the off-target evaluation points is sorted into a processing sequence in descending manner. The target layout pattern is identified, classified and grouped into a plurality of pattern blocks. The corrected pattern is modified according to the processing sequence, so as to converge the simulation contour of the corrected pattern being modified to be close to the target layout pattern.

### CROSS-REFERENCE TO RELATED APPLICATION

This application claims the priority benefits of U.S. provisional application Ser. No. 61/870,788, filed on Aug. 28, 2013. The entirety of the above-mentioned patent applications is hereby incorporated by reference herein and made a part of this specification.

### BACKGROUND OF THE INVENTION

1. Field of the Invention

The invention relates to a pattern correction method, and more particularly, to an advanced correction method.

2. Description of Related Art

With great advance of integrated circuit (IC) nowadays, miniaturization and integration for devices therein is an inevitable trend and one of most important topics to be discussed in the field. In the semiconductor fabrication, photolithography is one the most important steps, thus, it is critical to ensure that a pattern of a photomask is accurately transferred onto a wafer In case the pattern is not accurately transformed, a tolerance of a critical dimension (CD) is significantly affected to reduce a resolution of exposure.

As integration gradually becomes higher and a size of the device gradually becomes smaller, it is also required that a distance between devices to be smaller. Therefore, in the photolithography, a deviation may generate in transferring the pattern due to influences of light ray, which is also known as an optical proximity effect (OPE). The optical proximity effect is induced by enlargement of a light beam caused by a scattering phenomenon when the light beam is projected on a wafer through a photomask. On the other hand, the light beam is reflected back again from a photoresist layer on the surface of the wafer through a semiconductor substrate of the wafer, which results in an interference phenomenon. Hence, repeated exposures may occur to change actual exposure dose on the photoresist layer.

An optical proximity correction (OPC) method is aimed to eliminate a deviation phenomenon of the critical dimension caused by the optical proximity effect. However, after a correction is made by using optical proximity correction method in conventional art, there is still a part of the patterns not matching to a target layout pattern. Currently, the part of the patterns not matching to the target layout pattern needs to be compared and corrected manually after off-target points are established. However, there are millions of the off-target points on the wafer to be compared and corrected manually. As result, besides that a lot of human resources as well costs may be consumed, it also takes a longer period of time for completing all tasks.

### SUMMARY OF THE INVENTION

The invention is directed to an advanced method as a replacement of a manual method to quickly and effectively correct a corrected pattern to converge a simulation contour of the corrected pattern to be close to a target layout pattern.

In an advanced correction method according to an embodiment of the invention, a corrected pattern is modified to converge a simulation contour of the corrected pattern to be close to a target layout pattern.

An advanced correction method is provided, which includes the following steps. A target layout pattern is provided, and the target layout pattern is dissected and a plurality of evaluation points are established. Then, the target layout pattern is modified by a correction model to obtain a corrected pattern. Next, a simulation is performed on the corrected pattern to obtain a simulation contour. Thereafter, a difference between the simulation contour and the target layout pattern at each of the evaluation points on the target layout pattern is calculated, and the evaluation points having the difference being greater than a standard value are classified into off-target evaluation points. Then, a plurality of risk weighting values of each of the off-target evaluation points are obtained according to a plurality of influential factors influencing the simulation contour to deviate from the target layout pattern and a plurality of preset condition ranges. Subsequently, the risk weighting values of each of the off-target evaluation points are summed up to obtain a risk sum value of each of the off-target evaluation points. Thereafter, the risk sum values of the off-target evaluation points are sorted into a processing sequence in descending manner. The target layout pattern is identified, classified and grouped into a plurality of pattern blocks. Thereafter, the corrected pattern is modified according to the processing sequence, so as to converge the simulation contour of the corrected pattern being modified to be close to the target layout pattern.

In an embodiment of the invention, the step of obtaining the risk weighting values of each of the off-target evaluation points further includes establishing a lookup table and obtaining the risk weighting values of each of the off-target evaluation points by looking up the lookup table, in which the lookup table includes information regarding the influential factors and the risk weighting values corresponding to the preset condition ranges.

In an embodiment of the invention, the influential factors include an off-target level, a target CD size, a segment type and a run length. The off-target level is a deviation between a plurality of target points of the target layout pattern and the off-target evaluation points.

In an embodiment of the invention, the risk weighting value is greater when the off-target level is greater, the target CD size is smaller, or the run length is longer.

In an embodiment of the invention, the segment type includes a Vert, a Run, a Line end or a combination thereof, the risk weighting value of the Run is greater than the risk weighting value of the Vert, and the risk weighting value of the Vert is greater than the risk weighting value of the Line end.

In an embodiment of the invention, the advanced correction method further includes establishing a plurality of specific layers, in which information regarding the target layout pattern, the corrected pattern, the simulation contour and the off-target evaluation points are respectively stored in one the specific layers.

In an embodiment of the invention, the step of modifying the corrected pattern is performed until a number of the off-target evaluation points are reduced to below a preset value or become zero.

In an embodiment of the invention, the step of modifying the corrected pattern is performed until the risk sum values of the off-target evaluation point are reduced to below a preset value or become zero.

An advanced correction method is provided, which includes the following steps. A target layout pattern is provided. The target layout pattern is dissected and evaluation points are established. Then, the target layout pattern is corrected by a correction model to obtain a corrected pattern. Next, a simulation is performed on the corrected pattern to obtain a simulation contour. Thereafter, a difference between the simulation contour and the target layout pattern at the evaluation points on the target layout pattern is calculated, and the evaluation points having the difference being greater than a standard value are classified into off-target evaluation points. Then, a plurality of risk weighting values of each of the off-target evaluation points are obtained according to a plurality of influential factors influencing the simulation contour to deviate from the target layout pattern and a plurality of preset condition ranges. Subsequently, the risk weighting values of each of the off-target evaluation points are summed up to obtain a risk sum value of each of the off-target evaluation points. The target layout pattern is identified, classified and grouped into a plurality of pattern blocks. A block risk sum value of each of the pattern blocks is obtained according to a regulation, and the regulation is related to the risk sum values of the off-target evaluation points in each of the pattern blocks. The block risk sum values are sorted into a processing sequence in descending manner. Thereafter, the corrected pattern is modified according to the processing sequence, so as to converge the simulation contour of the corrected pattern being modified to be close to the target layout pattern.

In an embodiment of the invention, the regulation includes determining the block risk sum value according to a maximum of the risk sum value in the off-target evaluation points in each of the pattern blocks.

In an embodiment of the invention, the regulation includes determining the block risk sum value according to a sum of the risk sum values of all of the off-target evaluation points in each of the pattern blocks.

In an embodiment of the invention, the step of identifying, classifying and grouping the target layout pattern having the off-target evaluation points into the pattern blocks includes: expanding the target layout pattern having the off-target evaluation points for a specific range to obtain a plurality of divided region, and defining a pattern in the divided region as a local pattern; and identifying, classifying and grouping the target layout pattern into the pattern blocks according to a local pattern in the divided regions.

In an embodiment of the invention, the step of obtaining the risk weighting values of each of the off-target evaluation points further includes establishing a lookup table and obtaining the risk weighting values of each of the off-target evaluation points by looking up the lookup table, in which the lookup table includes information regarding the influential factors and the risk weighting values corresponding to the preset condition ranges. In an embodiment of the invention, the influential factors include an off-target level, a target CD size, a segment type and a run length. The off-target level is a deviation between a plurality of target points of the target layout pattern and the off-target evaluation points.

In an embodiment of the invention, the risk weighting value is greater when the off-target level is greater, the target CD size is smaller, or the run length is longer.

In an embodiment of the invention, the segment type includes a Vert, a Run, a Line end or a combination thereof, the risk weighting value of the Run is greater than the risk weighting value of the Vert, and the risk weighting value of the Vert is greater than the risk weighting value of the Line end.

In an embodiment of the invention, the advanced correction method further includes establishing a plurality of specific layers, in which information regarding the target layout pattern, the corrected pattern, the simulation contour, the off-target evaluation points, and the off-target evaluation points with the off-target level being greater than a preset value are respectively stored in one the specific layers.

In an embodiment of the invention, the step of establishing the off-target evaluation points on the target layout pattern is performed before the step of identifying, classifying and grouping the target layout pattern into the pattern blocks.

In an embodiment of the invention, the step of establishing the off-target evaluation points on the target layout pattern is performed after the step of identifying, classifying and grouping the target layout pattern into the pattern blocks.

In an embodiment of the invention, the step of modifying the corrected pattern is performed until a number of the off-target evaluation points are reduced to below a preset value or become zero.

In an embodiment of the invention, the step of modifying the corrected pattern is performed until all the block risk sum values of the pattern blocks or a portion of the block risk sum values of the pattern blocks are reduced to below a preset value or become zero.

In the advanced correction method according to an embodiment of the invention, the processing sequence is determined according to the risk sum values, so as to effectively converge the simulation contour to be close to the target layout pattern within a short period of time.

In the advanced correction method according to an embodiment of the invention, by identifying, classifying and grouping the simulation contour into a plurality of pattern blocks and followed by determining the processing sequence according the risk sum values, a processing time may be further reduced, so as to converge the simulation contour to be close to the target layout pattern within a shorter period of time.

To make the above features and advantages of the disclosure more comprehensible, several embodiments accompanied with drawings are described in detail as follows.

### BRIEF DESCRIPTION OF THE DRAWINGS

FIG. 1 is a flow chart illustrating an advanced correction method according to first embodiment of the invention.

FIG. 2A is a top view illustrating a target layout pattern, a corrected pattern and a simulation contour.

FIG. 2B is a top view illustrating a target layout pattern and a simulation contour.

FIG. 3A is a flow chart illustrating an advanced correction method according to second embodiment of the invention.

FIG. 3B is a flow chart illustrating an advanced correction method according to third embodiment of the invention.

FIG. 4 is a schematic view illustrating pattern blocks having various local patterns.

### DESCRIPTION OF THE EMBODIMENTS

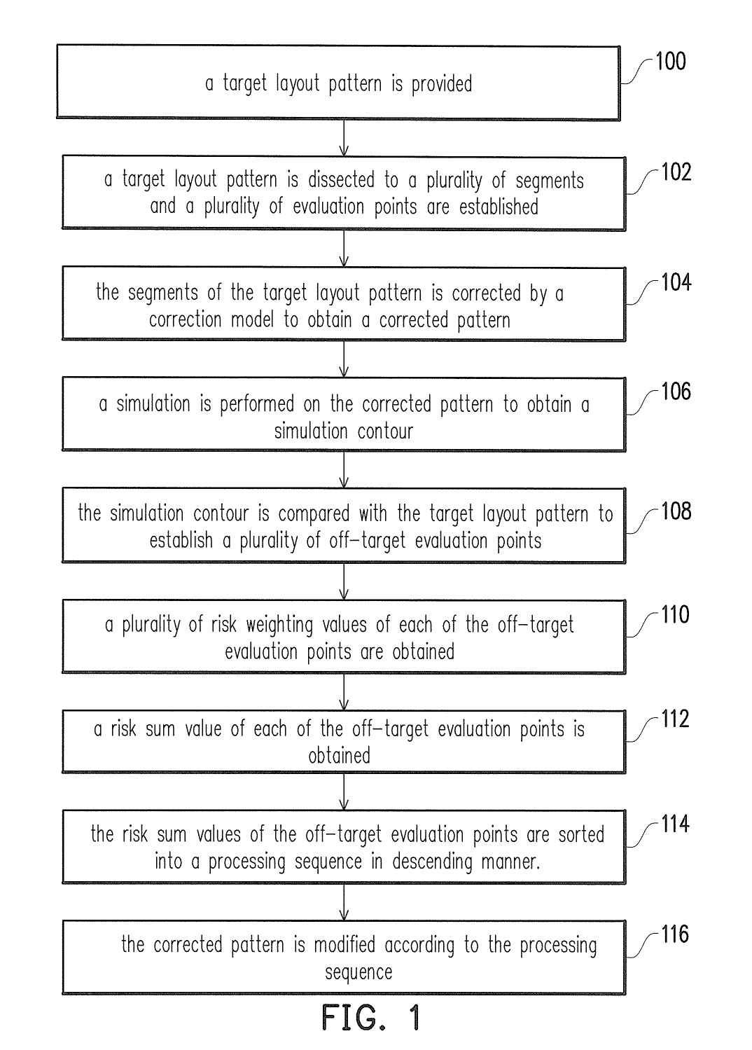

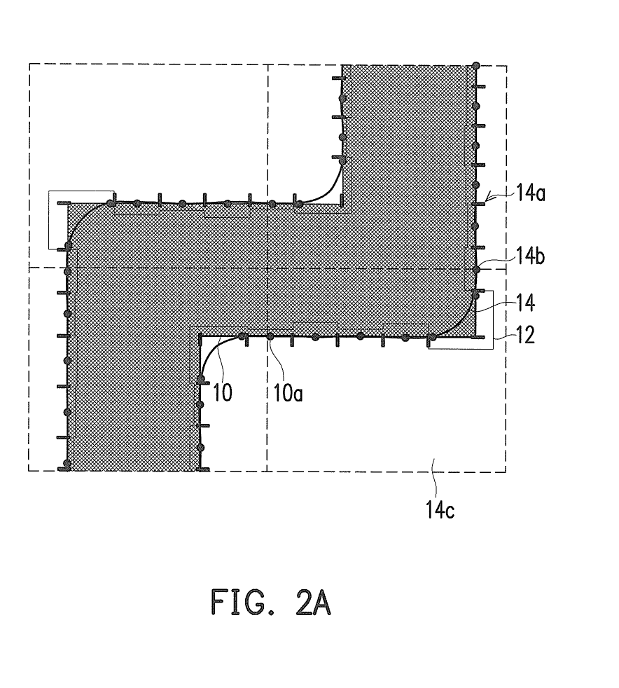

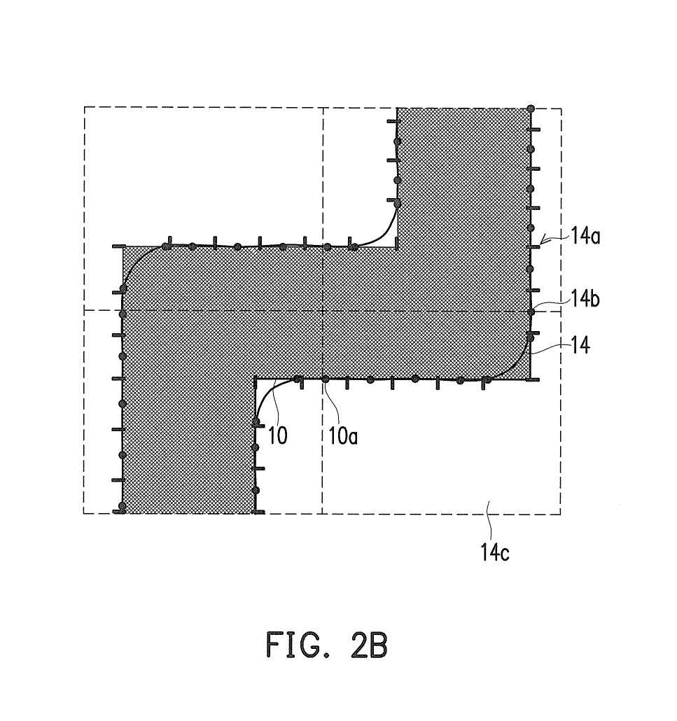

FIG. 1 is a flow chart illustrating an advanced correction method according to first embodiment of the invention. FIG. 2A is a top view illustrating a target layout pattern, a corrected pattern and a simulation contour.

Referring to FIG. 1 and FIG. 2A, in the advanced correction method according to first embodiment of the invention, a target layout pattern 10 is provided in step 100. The target layout pattern 10 refers to a layout pattern to be formed on a substrate. The target layout pattern 10 may include various patterns such as lines, blocks or holes. A shape of the target layout pattern may be, for example, a circle, an ellipse, a rectangle, a square, a strip or a pattern formed by combining and/or repeating any shapes.

Next, in step 102, the target layout pattern 10 is dissected to a plurality of segments 14a. Lengths of the segments 14a may be identical to, or different from each other. For instance, in a critical region or regions prone to affection of surrounding environment (e.g., the region including internal turns or external turns), the length of the segment 14a may be relatively shorter; in a non-critical region or regions not prone to affection of the surrounding environment (e.g., a strip pattern or a middle part of the line end), the length of the segment 14a may be relatively longer. Next, a point in each of the segments 14a is set to an evaluation point or target point 10a. The evaluation point 10a may be a center in the segment 14a, or any point set in the segment, the invention is not limited thereto.

Thereafter, in step 104, the plurality of segments 14a of the target layout pattern 10 is corrected by a correction model to obtain a corrected pattern 12. Herein, the correction model refers to any known correction models, such as model rule of an optical proximity correction model. Thereafter, in step 104, a simulation is performed on the corrected pattern 12 to obtain a simulation contour 14. The simulation refers to a simulation of actual processes, such as a lithography process or a photolithography process for transferring the corrected pattern 12 onto the substrate.

In view of FIG. 2B, the simulation contour 14 obtained by performing the simulation on the corrected pattern 12 obtained after the target layout pattern 10 is corrected by the correction model cannot be completely overlapped with the target layout pattern 10, which means that errors are still present. By using the advanced correction method of the invention, a pattern to be formed on the substrate can be obtained by effectively reducing the errors in a final simulation contour with respect to the target layout pattern.

FIG. 2B is a top view illustrating a target layout pattern and a simulation contour.

Referring to FIG. 1 and FIG. 2B, in step 108, the simulation contour 14 is compared with the target layout pattern 10 and a difference between the simulation contour 14 and the target layout pattern 10 at each of the evaluation points or target points 10a on the target layout pattern is calculated. When a difference between the simulation contour 14 and the target layout pattern 10 at the target point or evaluation point 10a on the target layout pattern 10 is greater than a standard value, the target point or evaluation point 10a is classified into off-target evaluation point 14b.

Thereafter, referring to FIG. 1, in step 110, a plurality of risk weighting values of each of the off-target evaluation points 14b are obtained according to a plurality of influential factors influencing the simulation contour 14 to deviate from the target layout pattern 10 and a plurality of preset condition ranges. The influential factors include an off-target level, a target CD size, a segment type or a run length and so on. The off-target level is a deviation between the off-target evaluation points 14b and the target points 10a of the target layout pattern 10. The target CD size refers to a size of the critical dimension of the target layout pattern 10 where the target points 10a corresponding to the off-target evaluation points 14b are located. The segment type refers to a segment type of the target layout pattern 10 where the target points 10a corresponding to the off-target evaluation points 14b are located. The segment type includes a Vert, a Run and Line end or a combination thereof, but the invention is not limited thereto. The run length refers to a run length of the segment 14a where the off-target evaluation points 14b are located.

In an embodiment, the step of obtaining a plurality of risk weighting values of each of the off-target evaluation points 14b may be accomplished by establishing a lookup table and obtaining the risk weighting values by looking up the lookup table. The lookup table includes information regarding the influential factors and the risk weighting values corresponding to the preset condition ranges. The lookup table may be established differently according to different shapes or different lengths of the target layout pattern 10. The lookup table may also be further used to set the risk weighting value in each of the preset condition ranges according to the influential factors such as the off-target level, the target CD size, the segment type or the run length. Table 1 is a schematic view illustrating the lookup table according to an exemplary embodiment.

TABLE 1

| | | | | |
|---|---|---|---|---|
| Off-target | off-target | 0.5 nm < off-target | 1 nm < off-target | 1.5 nm < off-target |
| level | level ≦ 0.5 nm | level ≦ 1 nm | level ≦ 1.5 nm | level ≦ 2 nm |
| | (risk weighting | (risk weighting | (risk weighting | (risk weighting |
| | value = 1) | value = 2) | value = 3) | value = 4) |
| Target CD size | target CD | 80 nm < target CD | 100 nm < target CD | 150 nm < target CD |
| | size ≦ 80 nm | size ≦ 100 nm | size ≦ 150 nm | size ≦ 200 nm |
| | (risk weighting | (risk weighting | (risk weighting | (risk weighting |
| | value = 2.5) | value = 2) | value = 1.5) | value = 1) |
| Segment type | Vert | Run | Line end | |
| | (risk weighting | (risk weighting | (risk weighting | |
| | value = 0.5) | value = 1) | value = 0.3) | |
| Run length | run length ≦ 50 nm | 50 nm < run | 100 nm < run | 150 nm < run length |
| | (risk weighting | length ≦ 100 nm | length ≦ 150 nm | (risk weighting |
| | value = 0.3) | (risk weighting | (risk weighting | value = 0.6) |
| | | value = 0.4) | value = 0.5) | |

Referring to Table 1, in the lookup table according to an exemplary embodiment, the off-target level may include four preset condition ranges, which are “off-target≦0.5 nm”, “0.5 nm<off-target≦1 nm”, “1 nm<off-target≦1.5 nm” and “1.5 nm<off-target≦2 nm”. The target CD size also includes four preset condition ranges, which are “CD size≦80 nm”, “80 nm<CD size≦100 nm”, “100 nm<CD size≦150 nm” and “150 nm<CD size≦200 nm”. The segment type includes three preset condition ranges which are the Vert, the Run and the Line end. The run length may also include four preset condition ranges, which are “run length≦50 nm”, “50 nm<run length≦100 nm”, “100 nm<run length≦150 nm” and “150 nm<run length”. In Table 1, it is only illustrated with four of the influential factors (the off-target level, the target CD size, the segment type and the run length) each having three or four preset conditions for example. However, the invention is not limited thereto. In other embodiments, more of the influential factors may also be included, and the influential factors may also have more or less of the preset condition ranges based on actual demands.

In Table 1, the risk weighting value is greater when the off-target level is greater or the run length is longer. The risk weighting value is smaller when the off-target level is smaller or the run length is shorter. In the segment type, the risk weighting value of the Run is greater than the risk weighting value of the Vert. The risk weighting value of the Vert is greater than the risk weighting value of the Line end. In addition, the off-target level or the target CD size has a greater influence to the pattern, thus the risk weighting value of the off-target level or the target CD size is greater than the risk weighting value of the run length or the segment type. However, the embodiment of the invention is not limited thereto. Each of the risk weighting values in the lookup table may be established based on actual demands (e.g., a process tolerance).

Next, referring to FIG. 1, in step 112, the risk weighting values of each of the off-target evaluation points 14b are summed up, so as to obtain a risk sum value of each of the off-target evaluation points 14b. Thereafter, in step 114, the risk sum values of the off-target evaluation points 14b are sorted into a processing sequence in descending manner.

Table 2 schematically illustrates information, the risk weighting value, and the risk sum value for each of the off-target evaluation points.

TABLE 2

| | Off-target | Off-target | Off-target | Off-target |
|---|---|---|---|---|
| | evaluation | evaluation | evaluation | evaluation |
| | point 1 | point 2 | point 3 | point 4 |
| Off-target level | 1.5 | 1 | 1.5 | 1.2 |
| Target CD size | 170 | 170 | 90 | 90 |
| Segment type | Vert | Run | Vert | Run |
| Run length | None | 56 | None | 50 |
| Risk | 3 + 1 + | 2 + 1 + | 3 + 2 + | 3 + 2 + 1 + |
| sum value | 0.5 = 4.5 | 1 + 0.4 | 0.5 = 5.5 | 0.3 = 6.3 |
| Processing | 3 | 4 | 2 | 1 |
| sequence | | | | |

Referring to Table 2, for instance, for the off-target evaluation point 2, the off-target level is 1 nm, the target CD size is 170 nm, the segment type is the Vert, and the run length is 56 nm. After a calculation is made to the off-target evaluation point 2 based on the lookup table of Table 2, the risk weighting value of the off-target level is 2, the risk weighting value of the target CD size is 1, the risk weighting value of the segment type is 1, and the risk weighting value of the run length is 0.4. Accordingly, the risk sum value of the off-target evaluation point 2 is 2+1+0.4=4.4. Similarly, other off-target evaluation points 1, 3 and 4 may also be calculated to obtain the risk sum values 4.5, 5.5 and 6 in that sequence. Therefore, in Table 2, the off-target evaluation points 1, 2, 3 and 4 are sorted by the risk sum values from large to small in a sequence of the off-target evaluation point 4, the off-target evaluation point 3, the off-target evaluation point 2 and the off-target evaluation point 1. Namely, the processing sequence is the off-target evaluation point 4, the off-target evaluation point 3, the off-target evaluation point 2 and the off-target evaluation point 1 in that sequence.

Thereafter, referring to FIG. 1, in step 116, the corrected pattern 12 is modified according to the processing sequence, so as to converge the simulation contour of the corrected pattern to be close to the target layout pattern 10. More specifically, it indicates that the simulation contour is converged when a number of the off-target evaluation points of simulation contour are reduced. Accordingly, the modifying step may be performed until the number of the off-target evaluation points is reduced to below a preset value, or may be performed until the risk sum values of the off-target evaluation points are reduced to below a preset value. However, the modifying step may be performed based on actual demands, it is not required to reduce all the risk sum values of the off-target evaluation points to the preset value or zero, or reduce the number of the off-target evaluation points of the simulation contour to zero. In other words, for the off-target evaluation points with the risk sum value being relatively higher or the process tolerance being relatively lower, the risk sum value may be reduced to below a preset value (or zero) after the modifying step is performed. For the off-target evaluation points with the risk sum value being relatively lower or the process tolerance being relatively higher, after the modifying step is performed, it is not necessarily to reduce the risk sum value. Although the block risk sum value may be slightly increased, the final simulation contour is less likely to suffer too much negative impact. In this case, the modifying step may be stopped, and it is deemed that the simulation contour is converged to be close to the target layout pattern 10.

In order simplify information or processes, a plurality of specific layers may be established in a processing software, and different information may be stored in different one of the specific layers to facilitate searching and processing in subsequent steps. For instance, information regarding the target layout pattern 10 may be stored in the specific layer 1. Information regarding the corrected pattern 12 may be stored in the specific layer 2. Information regarding the simulation contour 14 may be stored in the specific layer 3. Information regarding the target point or evaluation point 10a may be stored in the specific layer 4. Besides, based on actual demands, a specific layer 5 may be used to store the off-target evaluation point 14b in which the off-target level of the off-target evaluation point 14b is above the preset value (e.g., the off-target level>0.5 nm). Next, the subsequent steps may be performed, for example, the simulation contour 14 is compared with the target layout pattern 10 to obtain a plurality of risk weighting values of each of the off-target evaluation points 14b. The preset value of the off-target level may be set according to actual demands and has no particular limitations. In other words, the specific layer 5 may be used to store the off-target evaluation points 14b with the off-target level being greater than the preset value, so that the subsequent steps such as summing up the risk weighting values, sorting the processing sequence and so on may be performed on the off-target evaluation points 14b in the specific layer 5 being outputted. It is not required to perform steps such as summing up the risk weighting values, sorting the processing sequence and so on, for the target point or evaluation point 10a not being stored in the specific layer 5.

In first embodiment, the processing sequence is determined according to a sequence of the risk sum values of the off-target evaluation point 14b, but the invention is not limited thereto. Generally, the target layout pattern to be applied on one photomask may include millions of the off-target evaluation points. However, the target layout pattern where the target points or evaluation points 10a are located and the simulation contour 14 thereof may also include a plurality of segments in which the patterns or the environment are identical to one another. Accordingly, the advanced correction method may also be used to further identify, classify and group the target layout pattern 10, so as to optimize the correction of the patterns in a quicker and effective manner.

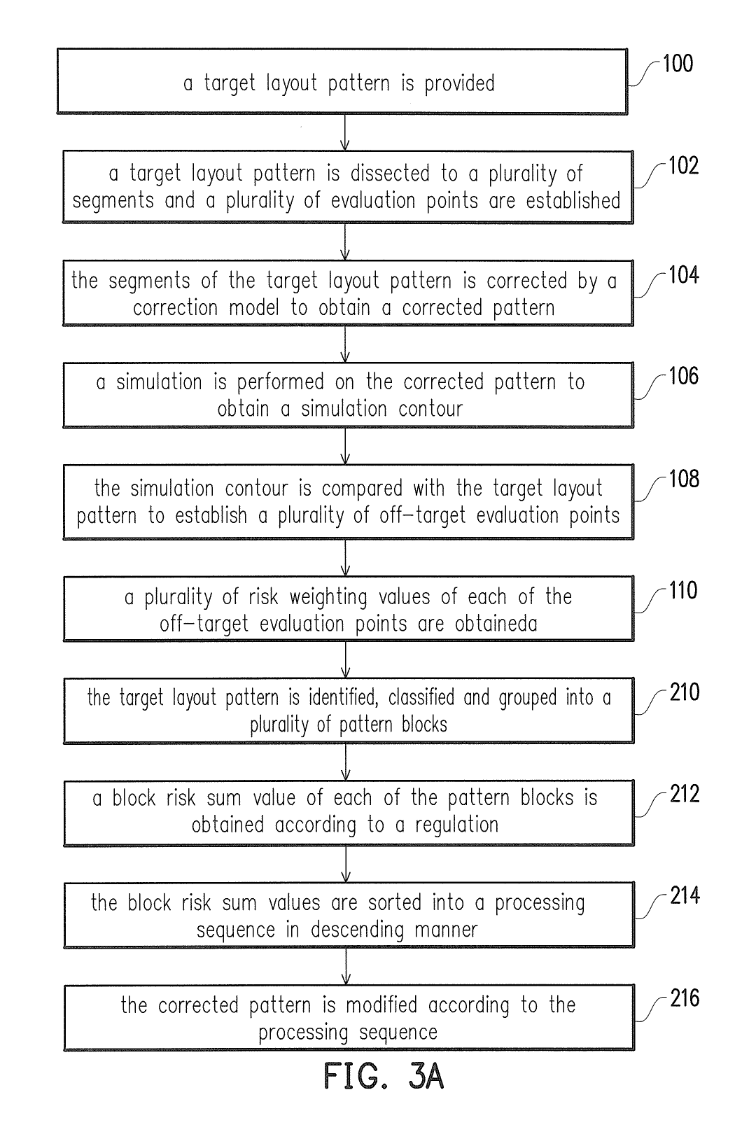

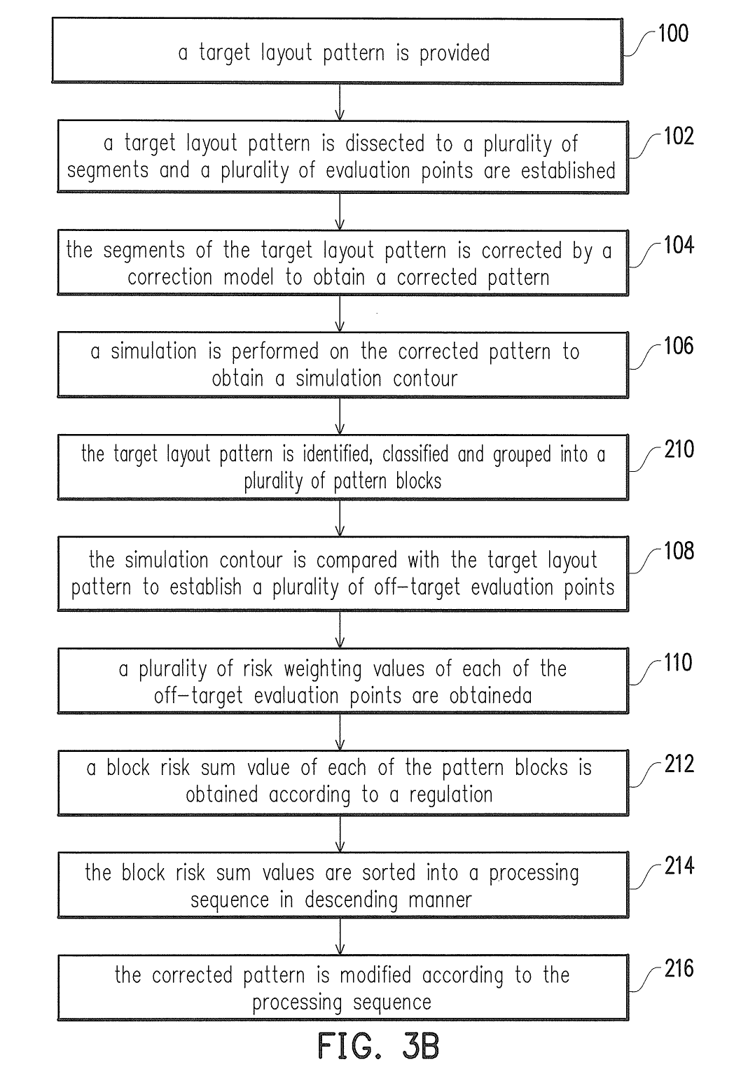

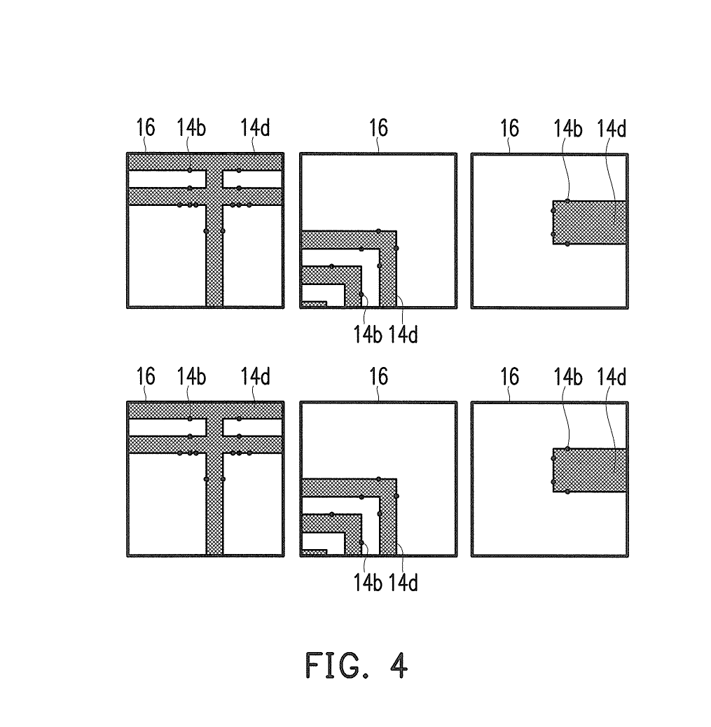

FIG. 3A is a flow chart illustrating an advanced correction method according to second embodiment of the invention. FIG. 3B is a flow chart illustrating an advanced correction method according to third embodiment of the invention. FIG. 4 is a schematic view illustrating pattern blocks having various local patterns.

Referring to FIG. 3A, FIG. 1 and FIG. 4, in second embodiment, step 210 is performed after step 110 depicted in FIG. 1, in which the target layout pattern 10 having the off-target evaluation points 14b is expanded for a specific range to obtain divided regions 14c, and a pattern in the divided region 14c is defined as a local pattern 14d. Thereafter, the pattern blocks 16 are identified, classified and grouped according to the local pattern 14d in the divided region 14c. Detailed steps for obtaining the pattern blocks 16 include: expanding for a predetermined range value with the off-target evaluation point 14b on the target layout region 10 as a center to obtain the divided region 14c; comparing the local pattern 14d in the divided region 14c with a similarity to be set; and classifying local pattern 14d into the pattern block 16 of the same type if the similarity is equal to or higher than a set value. A shape of the divided region 14c includes a square, a rectangle or a combination thereof. For instance, the divided region 14c may be the square having a side length being 1 μm. The dividing method thereof may be accomplished by setting a coordinate axis with a zero point selected from any one of the off-target evaluation points. However, the size and the shape of the divided region 14c are not limited thereto. The local pattern 14b in the divided region 14c having the off-target evaluation points 14b may be identified, classified and grouped into the pattern blocks 16 by using any known machines such as a machine for measuring a yield rate, or any electronic design automation (EDA) software having the same capability.

Referring to FIG. 4, in an embodiment, after dividing, identifying, classifying and grouping the target layout pattern 10 originally included with millions of the off-target evaluation points, approximately 100 of pattern blocks 16 may be identified, classified and grouped according to the local pattern 14d of the divided region 14c.

Referring to FIG. 3A, in step 212, a block risk sum value of each of the pattern blocks 16 is obtained according to a regulation. The regulation is related to the risk sum value of the off-target evaluation point 14b in each of the pattern blocks 16. More specifically, in an embodiment, the regulation may include determining the block risk sum value according to a maximum of the risk sum values in the off-target evaluation points 14b in each of the pattern blocks 16. In another embodiment, the regulation may also include determining the block risk sum value according to a sum of the risk sum values of all of the off-target evaluation points 14b in each of the pattern blocks 16. However, the invention is not limited thereto. In other embodiments, based on actual conditions and requirements, the block risk sum value may also be determined according a sum of any number of the risk sum values among a range from the maximum of the risk sum values to a minimum of the risk sum value in each of the pattern blocks 16.

Next, referring to FIG. 3A, in step 214, the block risk sum values are sorted into a processing sequence in descending manner. Thereafter, in step 216, the corrected pattern 12 is modified according to the processing sequence, so as to converge the simulation contour of the corrected pattern being modified to be close to the target layout pattern 10.

More specifically, it indicates that the simulation contour is converged when a number of the off-target evaluation points of simulation contour are reduced. Accordingly, the modifying step may be performed until a number of the off-target evaluation points is reduced to below a preset value, or may be performed until the block risk sum values are reduced to below a preset value or even become zero. However, the modifying step may be performed based on actual demands, it is not required to reduce the number of the off-target evaluation points of the simulation contour to zero, or reduce all the block risk sum values to the preset value or zero. In other words, for the off-target evaluation points with the risk sum value being relatively higher or the process tolerance being relatively lower, the block risk sum value may be reduced to below a preset value (or zero) after the modifying step is performed. For the pattern blocks with the block risk sum value being relatively lower or the process tolerance being relatively higher, it is not required for the block risk sum value to be reduced after the modifying step is performed. Although the block risk sum value may be slightly increased, the final simulation contour is less likely to suffer too much negative influence. In this case, the modifying step may be stopped, and it is deemed that the simulation contour is converged to be close to the target layout pattern 10.

In order simplify information or processes, a plurality of specific layers may be established in a processing software, and different information may be stored in different one of the specific layers to facilitate searching and processing in subsequent steps. For instance, information regarding the target layout pattern 10 may be stored in the specific layer 1. Information regarding the corrected pattern 12 may be stored in the specific layer 2. Information regarding the simulation contour 14 may be stored in the specific layer 3. Information regarding the target point 10a may be stored in the specific layer 4. Besides, based on actual demands, a specific layer 5 may be used to store the target point or evaluation point 10a defined as the off-target evaluation point 14b for having the off-target level greater than the preset value (e.g., the off-target level>0.5 nm). When proceeding to the subsequent processes, the specific layer 5 may be directly outputted before performing the subsequent processes (e.g., grouping the local patterns 14d). In other words, the specific layer 5 may be used to store the target point or evaluation point 10a (i.e., off-target evaluation points 14b) with the off-target level being greater than a preset value, so that the subsequent steps such as summing up the block risk weighting values, sorting the processing sequence and so on may be performed on the pattern blocks 16 where the off-target evaluation points 14b with the off-target level being greater than the preset value are located. It is not required to perform steps such as summing up the block risk weighting values, sorting the processing sequence and so on, for the target point or evaluation point 10a not being stored in the specific layer 5.

In second embodiment, the target layout pattern 10 is identified, classified and grouped into the pattern blocks 16 after the off-target evaluation points 14b are established. However, the invention is not limited thereto. Referring to FIG. 3B, in third embodiment of the invention, the target layout pattern 10 may be identified, classified and grouped into the pattern blocks 16 (the step 210) before the off-target evaluation points 14b are established (the step 108), and the subsequent processes (the steps 110 and 212˜216) may be performed thereafter.

The advanced correction method of the invention may be applied in an optical proximity correction process, but the invention is not limited thereto. The advanced correction method of the invention may be applied in viewing and modifying any related patterns.

The advanced correction method of the first embodiment may be stored in a database of known machines (e.g., an OPC machine). In the advanced correction methods of second embodiment and third embodiment, a machine for measuring a yield rate, or any EDA software having the same capability may be adopted to identify, classify and group the target layout pattern having the off-target evaluation points into the pattern blocks. The rest of the said steps may be stored in a database of any known machines (e.g., the OPC machine). However, the advanced correction method may also be implemented into a computer readable program code for a computer readable recording medium. The computer readable recording medium may be any data storage devices capable of storing data and being read by a computer system. Examples of the computer readable recording medium include a read-only memory (ROM), a random-access memory (RAM), a CD-ROM, a magnetic tape, a floppy disk, a flash memory, an optical data storage device and a carrier wave (such as data transmission through a wired or a wireless transmission paths), but the invention is not limited thereto. The computer-readable recording medium may also be distributed over network-coupled computer systems so that the computer-readable code is stored and executed in a distributed fashion. Furthermore, persons with ordinary skill in the art may realize the invention by functional programs, program codes or program segments according to claims of the invention.

Based on above, the advanced correction method of the invention is capable of establishing the risk weighting values of the off-target evaluation points according to the influential factors influencing the simulation contour to deviate from the target layout pattern and the corresponding condition ranges. Next, the risk sum value of each of the off-target evaluation points is calculated. Then, the processing sequence is determined according to the risk sum values, so as to effectively converge the simulation contour to be close to the target layout pattern. As a result, a quality photomask made is improved. In addition, by identifying, classifying and grouping the target layout pattern and the simulation contour thereof into a plurality of pattern blocks and determining the processing sequence according to the high and low values of the risk sum values, a processing time may be reduced, so as to converge the simulation contour to be close to the target layout pattern within a shorter period of time. As a result, a quality photomask made is improved.

It will be apparent to those skilled in the art that various modifications and variations can be made to the structure of the disclosed embodiments without departing from the scope or spirit of the disclosure. In view of the foregoing, it is intended that the disclosure cover modifications and variations of this specification provided they fall within the scope of the following claims and their equivalents.

What is claimed is:

1. An advanced correction method, comprising:
providing a target layout pattern;
dissecting the target layout pattern and establishing a plurality of evaluation points;
correcting the target layout pattern by a correction model to obtain a corrected pattern;
performing a simulation on the corrected pattern to obtain a simulation contour;
calculating a difference between the simulation contour and the target layout pattern at each of the evaluation points on the target layout pattern, wherein the evaluation point having the difference being greater than a standard value is classified into an off-target evaluation point;
obtaining a plurality of risk weighting values of each of the off-target evaluation points according to a plurality of influential factors influencing the simulation contour to deviate from the target layout pattern and a plurality of preset condition ranges.
summing up the risk weighting values of each of the off-target evaluation points to obtain a risk sum value of each of the off-target evaluation points;
sorting the risk sum values of the off-target evaluation points into a processing sequence in descending manner;
identifying, classifying and grouping the target layout pattern into a plurality of pattern blocks; and
modifying the corrected pattern according to the processing sequence to converge the simulation contour of the corrected pattern being modified to be close to the target layout pattern.

2. The advanced correction method of claim 1, wherein obtaining the risk weighting values of each of the off-target evaluation points further comprises establishing a lookup table and obtaining the risk weighting values of each of the off-target evaluation points by looking up the lookup table, wherein the lookup table includes information regarding the influential factors and the risk weighting values corresponding to the preset condition ranges.

3. The advanced correction method of claim 2, wherein the influential factors comprises:
an off-target level, wherein the off-target level is a deviation between the off-target evaluation points and the target layout pattern;
a target CD size;
a segment type; and
a run length.

4. The advanced correction method of claim 3, wherein the risk weighting value is greater when the off-target level is greater, the target CD size is smaller, or the run length is longer.

5. The advanced correction method of claim 3, wherein the segment type includes a Vert, a Run, a Line end or a combination thereof, the risk weighting value of the Run is greater than the risk weighting value of the Vert, and the risk weighting value of the Vert is greater than the risk weighting value of the Line end.

6. The advanced correction method of claim 1, further comprises establishing a plurality of specific layers, wherein information regarding the target layout pattern, the corrected pattern, the simulation contour and the off-target evaluation points are respectively stored in one the specific layers.

7. The advanced correction method of claim 1, wherein the correction model comprises an optical proximity correction model.

8. The advanced correction method of claim 1, wherein modifying the corrected pattern is performed until a number of the off-target evaluation points are reduced to below a preset value or become zero.

9. The advanced correction method of claim 1, wherein modifying the corrected pattern is performed until the risk sum values of the off-target evaluation point are reduced to a preset value or become zero.

10. An advanced correction method, comprising:
providing a target layout pattern;
dissecting the target layout pattern and establishing a plurality of evaluation points;
correcting the target layout pattern by a correction model to obtain a corrected pattern;
performing a simulation on the corrected pattern to obtain a simulation contour;
calculating a difference between the simulation contour and the target layout pattern at each of the evaluation points on the target layout pattern, wherein the evaluation point having the difference being greater than a standard value is classified into an off-target evaluation point;
obtaining a plurality of risk weighting values of each of the off-target evaluation points according to a plurality of influential factors influencing the simulation contour to deviate from the target layout pattern and a plurality of preset condition ranges;
summing up the risk weighting values of each of the off-target evaluation points to obtain a risk sum value of each of the off-target evaluation points;
identifying, classifying and grouping the target layout pattern into a plurality of pattern blocks;
obtaining a block risk sum value of each of the pattern blocks according to a regulation, wherein the regulation is related to the risk sum values of the off-target evaluation points in each of the pattern blocks;
sorting the block risk sum values into a processing sequence in descending manner; and
modifying the corrected pattern according to the processing sequence to converge the simulation contour of the corrected pattern being adjusted to be close to the target layout pattern.

11. The advanced correction method of claim 10, wherein the regulation includes determining the block risk sum value according to a maximum of the risk sum values in the off-target evaluation points in each of the pattern blocks.

12. The advanced correction method of claim 10, wherein the regulation includes determining the block risk sum value according to a sum of the risk sum values of all of the off-target evaluation points in each of the pattern blocks.

13. The advanced correction method of claim 11, wherein identifying, classifying and grouping the target layout pattern having the off-target evaluation points into the pattern blocks comprises:
expanding the target layout pattern having the off-target evaluation points for a specific range to obtain a plurality of divided region, wherein a pattern in the divided region is defined as a local pattern; and
identifying, classifying and grouping the pattern blocks according to a local pattern in the divided regions.

14. The advanced correction method of claim 10, wherein obtaining the risk weighting values of each of the off-target evaluation points further comprises establishing a lookup table and obtaining the risk weighting values of each of the off-target evaluation points by looking up the lookup table, wherein the lookup table includes information regarding the influential factors and the risk weighting values corresponding to the preset condition ranges.

15. The advanced correction method of claim 10, wherein the influential factors comprises:
an off-target level, wherein the off-target level is a deviation between the off-target evaluation points and a plurality of target points of the target layout pattern;
a target CD size;
a segment type; and
a run length.

16. The advanced correction method of claim 15, wherein the risk weighting value is greater when the off-target level is greater, the target CD size is smaller, or the run length is longer.

17. The advanced correction method of claim 15, wherein the segment type includes a Vert, a Run, a Line end or a combination thereof, the risk weighting value of the Run is greater than the risk weighting value of the Vert, and the risk weighting value of the Vert is greater than the risk weighting value of the Line end.

18. The advanced correction method of claim 10, further comprises establishing a plurality of specific layers, wherein information regarding the target layout pattern, the corrected pattern, the simulation contour, the off-target evaluation points, and the off-target evaluation points with the off-target level being greater than a preset value are respectively stored in one the specific layers.

19. The advanced correction method of claim 10, wherein establishing the off-target evaluation points on the target layout pattern is performed before identifying, classifying and grouping the target layout pattern into the pattern blocks.

20. The advanced correction method of claim 10, wherein establishing the off-target evaluation points on the target layout pattern is performed after identifying, classifying and grouping the target layout pattern into the pattern blocks, and modifying the corrected pattern is performed until a number of the off-target evaluation points are reduced to below a preset value or become zero.

21. The advanced correction method of claim 10, wherein modifying the corrected pattern is performed until all of the block risk sum values of the pattern blocks or a portion of the block risk sum values of the pattern blocks is reduced to a preset value or become zero.
